(19) United States
(12) Patent Application Publication
(10) Pub. No.: US 2010/0098550 A1
(43) Pub. Date: Apr. 22, 2010

(54) Method for coating of a base body and also a workpiece

(75) Inventor: Wolfram Beele, Ratingen (DE)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sulzer Metco Coatings B.V., Lomm (NL)

(21) Appl. No.: 11/598,213

(22) Filed: Nov. 10, 2006

(30) Foreign Application Priority Data
Nov. 14, 2005 (EP) 05405631.2

(51) Int. Cl. F01D 5/28; C23C 16/44

(52) U.S. Cl. 416/241 R; 427/255.23

(57) ABSTRACT

A method for the coating of a base body is proposed, in which a layer of a platinum modified aluminide of the kind PtMAl is produced on the base body wherein M designates the metals iron (Fe) or nickel (Ni) or cobalt (Co) or combinations of these metals, wherein the layer is produced by means of a physical deposition out of the gas phase (PVD), wherein at least the two components aluminium (Al) and metal M are physically deposited out of the vapour phase, with the deposition being carried out at a process pressure of at least 0.1 mbar, preferably of at least 0.4 mbar and especially between 0.4 mbar and 0.6 mbar. A workpiece is further proposed, in particular a turbine blade, with a base body on which a layer is applied which is produced using a method of this kind.

This application claims the priority of European Patent Application No. 05405631.2, filed Nov. 14, 2005, the disclosure of which is incorporated herein by reference.

The method relates to a method for coating of a base body in accordance with the pre-characterising part of the independent claim 1 and also to a workpiece with a base body on which a layer is applied in accordance with this method.

In the operation of turbines which are used for example as engines for aeroplanes or as land-based industrial gas turbines, the aim is to realise as high a temperature as possible of the gases which arise through combustion because the efficiency of the turbine improves the higher the temperature of the gas. In this arrangement the gas temperature often exceeds the melting temperature of the metallic compounds from which the parts are manufactured which come into contact with the hot gas, for example the turbine blades and the combustion chamber.

For this reason it is usual, above all in the high temperature region of the turbine, on the one hand, to select as material metallic compounds, which possess very good mechanical characteristics even at very high temperatures and, on the other hand, to actively cool the workpieces, such as for example the turbine blades and/or to provide them with protective layers, for example with a thermal protective layer TBC (thermal barrier coating).

As a rule super-alloys which are usually nickel-based or cobalt-based alloys are used as material for the workpieces of the turbine which are the most loaded thermally. These super-alloys do have an extraordinary strength at very high temperatures, however their characteristics with regard to oxidation resistance and hot corrosion resistance in the aggressive atmosphere of the turbine are often not adequate. In order to solve this problem, it is known to provide the super-alloys with a layer, which has a very good hot corrosion resistance.

For the production of hot corrosion and hot oxidation resistant layers on workpieces made of super-alloys it is known for example to use platinum modified aluminides of the kind PtMAl, wherein M denotes the metals iron (Fe) or nickel (Ni) or cobalt (Co) or combinations of these metals. In these aluminides a part of the metal M is replaced by platinum (Pt). These are diffusion layers. For the production of the layer, a platinum layer is first applied to the base body by a galvanic process. Subsequently, in a further method step, the base body is alitised. This takes place by pack cementation or by chemical vapour deposition (CVD) at high temperatures and preferably by a subsequent heat treatment.

A platinum modified aluminide layer of this kind is disclosed, for example in EP-A-1-111 091. Here the base body is of a nickel-based alloy for example. Following electrochemical application of the platinum layer the alitising takes place by means of CVD. In this arrangement, on the one hand, the aluminium diffuses through the platinum layer into the boundary region of the base body and, on the other hand, nickel diffuses out of the base body through the platinum layer to the outside. This leads to the formation of a platinum modified nickel aluminide layer.

It is also known from EP-A-1 209 247 (corresponds to U.S. Pat. No. 6,602,356) to produce a platinum modified aluminide layer by galvanic application of platinum and subsequent alitising by means of a CVD process, wherein during the CVD process an active element, for example hafnium (Hf), is additionally introduced into the layer.

Starting from the prior art, it is an object of the invention to propose a different method for the coating of a base body in which a layer out of a platinum modified aluminide is produced. Furthermore, the invention is intended to make available a workpiece with a base body and a layer produced in this manner.

The subjects of the invention satisfying these objects are characterised by the features of the independent claims in the respective category.

Thus, in accordance with the invention, a method for the coating of a base body is proposed in which a layer of a platinum modified aluminide of the kind PtMAl is produced on the base body, wherein M designates the metals iron (Fe) or nickel (Ni) or cobalt (Co) or combinations of these metals, wherein the layer is produced by means of a physical deposition out of the gas phase (PVD), wherein at least one of the components platinum (Pt), aluminium (Al), metal M is physically deposited out of the vapour phase, with at least the two components aluminium (Al) and metal M being physically deposited from the vapour phase and with the deposition being carried out at a process pressure of at least 0.1 mbar, preferably of at least 0.4 mbar, and especially between 0.4 mbar and 0.6 mbar.

In contrast to the previously known methods for producing platinum modified aluminide layers in which for example a diffusion layer is produced by means of CVD methods via chemical processes, wherein the platinum is galvanically deposited in advance in the form of a thin layer, in the method in accordance with the invention at least the two components metal M and aluminium (Al) are physically deposited out of the vapour phase, with this deposition being carried out at a process pressure of at least 10⁻¹ mbar. This has the decisive advantage that, in addition to the aluminium, the metal M, i.e. for example nickel, cobalt or iron, is also made available by a PVD process and does not have to be supplied by diffusion processes from the base body. Thus, an undesired graduation of the concentration of the metal M or of the aluminium concentration can also be avoided, the chemical composition of the layer can be set precisely.

Through the relatively high process pressure in comparison to other PVD processes, such as, for example, EB-PVD (electron beam PVD), the possibly greatly differing vapour pressures of the individual components no longer have a significant role to play with respect to the composition of the layer to be produced. In particular, the high speed (HS) PVD process is suitable for the method of the invention.

The metal M and the aluminium are preferably made available simultaneously by means of PVD.

In a first preferred way of carrying out the process, all components aluminium (Al), platinum (Pt) and the metal M are physically deposited out of the vapour phase. This has the result that the generated layer is a deposited layer, which is arranged to 80-90% on the base body, for example, while in the case of the diffusion layers, a considerably larger part of the layer, 50% for example, is generated in the wall of the base body. This is particularly advantageous as regards repairs in which typically the layer has to be removed before repair of the base body. Using the method in accordance with the invention, the so-called “lost wall” effect can be reduced, in which a considerable amount of material has to be removed from the base body in case of repair. Furthermore, by making all three components available by means of PVD, the chemical composition of the layer can be very precisely set in controlled manner. Concentration changes as a function of the layer thickness, such as are usual during the generation of diffusion layers, can be avoided by means of the method of the invention. Naturally, it is also possible by appropriate conduction of the method to bring about intentional concentration changes of the components over the thickness of the layer.

Moreover, since in this method of carrying out the process, the metal M, in other words for example nickel (Ni), is physically deposited out of the vapour phase, the metal does not have to migrate out of the base body into the layer by outward diffusion. Thus, the composition, or rather the stoichiometry of the layer, can be controlled considerably more simply and precisely.

A further advantage of this way of carrying out the process is that through the physical deposition of the components, contaminants in the layer can be avoided, such as are caused by the chemical processes in the known methods. Thus, for example, in the galvanic deposition of platinum, the residues of the salts lead to the undesired incorporation of sulphur (S) and phosphorous (P). This is not possible in the method in accordance with the invention because platinum is physically deposited directly in metallic form out of the vapour phase.

However, method steps are possible in which not all components of the layer are applied by means of PVD.

It is thus possible, for example, that the platinum is galvanically applied and the components aluminium and metal M are physically deposited out of the vapour phase. Then the platinum is applied in a manner known per se using a galvanic method and subsequently the aluminium and the metal M are applied by means of a PVD process.

Depending on the application it can be advantageous for the layer to additionally contain at least one active element, wherein each active element is selected from the group which includes scandium (Sc), yttrium (Y), lanthanum (La), titanium (Ti), zirconium (Zr), hafnium (Hf), vanadium (V), niobium (Nb), tantalum (Ta), silicon (Si) and the lanthanides cerium (Ce) to lutetium (Lu). It is known that by the addition of active elements the characteristics of the layer can be influenced positively. At least one active element is advantageously physically deposited out of the gas phase. Using this method in accordance with the invention it is clearly simpler to control the chemical composition of the layer and to adjust it to desired values. This can be ensured, for example, by a corresponding composition and design of the cathodes, from which the components for the layer are released. A considerably wider range of elements or rather element combinations and/or concentrations becomes accessible through the use of the PVD method. In the known CVD methods it is, namely, often difficult to enrich the halogenides usually used for the process with active elements in adequate concentrations.

One to three active elements are then preferably deposited, which amount in total to 0.2% to 10% by weight of the layer.

Having regard to an improvement of the corrosion characteristics it is an advantageous measure, when chrome (Cr) is physically deposited out of the vapour phase, which amounts to 3% to 25% by weight of the layer in total.

In accordance with a preferred way of carrying out the method, a platinum layer is initially deposited in a first method step, and the other components of the layer are subsequently deposited in at least one further method step.

In accordance with another preferred way of carrying out the process, all components of the layer are deposited in one method step, essentially simultaneously. This makes possible a very fast and uniform layer build-up.

In the method in accordance with the invention the deposition is particularly preferably carried out by means of high-speed PVD (HS-PVD). Using this gas flow sputtering method, very high deposition rates of, for example, up to 100 μm/h can namely be achieved.

Depending on the application it is an advantageous measure when a thermal protection layer (TBC) is subsequently applied on the layer. All TBC materials known per se, such as yttrium (part) stabilised zirconium oxide for example, are suitable for this.

In accordance with the invention there is further proposed a workpiece with a base body on which a layer in accordance with the invention is applied.

In accordance with a preferred use, the workpiece is designed as a turbine blade.

Further advantageous measures and preferred designs of the invention result from the dependent claims.

The invention will be explained in more detail in the following with reference to the drawing. The schematic drawing shows:

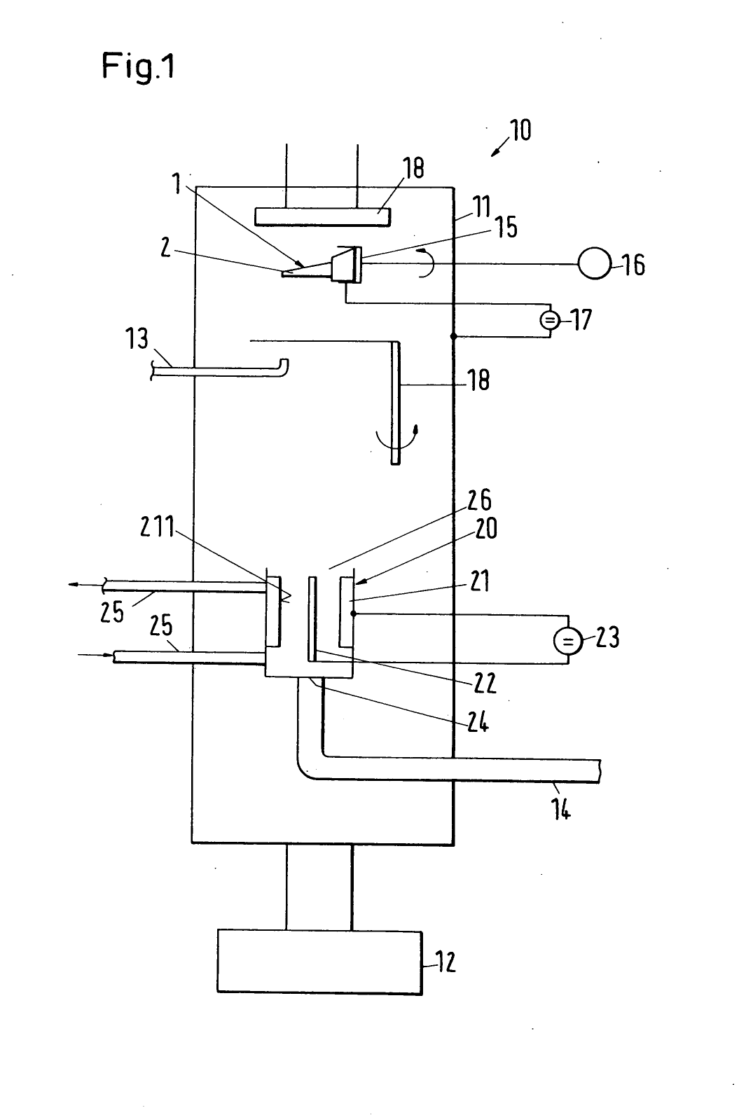

FIG. 1 a schematic illustration of an apparatus for the carrying out of the method in accordance with the invention, and

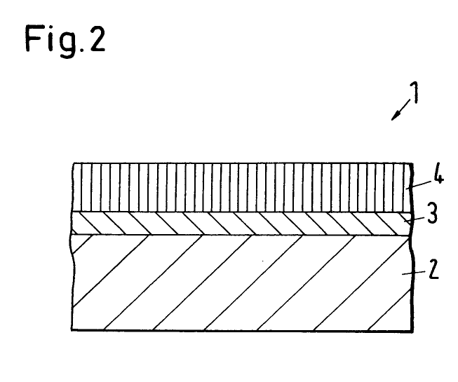

FIG. 2 a schematic sectional view of an embodiment of a workpiece in accordance with the invention.

In the following description relative place names such as “top”, “bottom”, “above”, “beneath” . . . relate to the positions used in FIGS. 1 and 2. It goes without saying that these designations of position are to be understood by way of example.

In the method in accordance with the invention for the coating of a base body 2 (FIG. 1) a layer 3 (FIG. 2) is produced on the base body 2 out of a platinum modified aluminide of the kind PtMAl, wherein M designates the metals iron (Fe) or nickel (Ni) or cobalt (Co) or combinations of these metals. The method in accordance with the invention is characterised in that at least the two components aluminium (Al) and metal M of the layer 3 are produced by means of a physical deposition out of the vapour phase, in other words by means of a PVD (physical vapour deposition) method, with the deposition being carried out at a process pressure of 10⁻¹ mbar (Millibar), preferably of at least 4×10⁻¹ mbar and especially between 4×10⁻¹ mbar and 6×10⁻¹ mbar. In principal, all PVD methods known per se, which can be carried out at such process pressures, can be used for the method in accordance with the invention. These are known sufficiently to the person averagely skilled in the art. Reference is made in the following with exemplary character to the method of the high-speed PVD, HS-PVD (HS: high speed) which is particularly preferred for practical use.

Reference is further made to the preferred way of carrying out the process, in which all components of the layer 3 are deposited physically out of the vapour phase. It goes without saying that other ways of carrying out the process are also possible. Thus it is, for example, possible that the platinum is galvanically applied and the components aluminium and metal M are physically deposited out of the vapour phase. Then platinum is applied in a manner known per se using a galvanic method and subsequently the aluminium and the metal M are applied by means of a PVD process.

Furthermore, it is also assumed with like exemplary character, that nickel can be used as metal M, i.e. the layer 3 is a platinum modified nickel aluminide (PtNiAl) layer. The explanations naturally apply analogously for iron, cobalt or for combinations of these three elements as the metal M.

FIG. 1 shows in a schematic illustration an apparatus, which is suitable for the carrying out of a method in accordance with the invention. This apparatus is designated throughout with the reference numeral 10. In this special case the apparatus 1 is suitable for carrying out HS-PVD. HS-PVD is a gas flow sputtering process, or a reactive gas flow sputtering process. The gas flow sputtering is described for example in WO-A-98/13531 and in DE-A-42 35 453. In this method an inert gas, for example argon, is fed through a hollow cathode, in which an anode is arranged. The argon atoms are ionised and then impinge on the cathode, by which means cathode material is sputtered and is then conveyed out of the cathode by the stream of inert gas to the substrate. In the case of reactive gas flow sputtering a feed for a reactive gas, for example oxygen, is provided between the outlet of the cathode and the substrate, by which the sputtered cathode material is oxidised.

The apparatus 10, which is schematically illustrated in FIG. 1, will now be described in the following.

The apparatus 10 for the HS-PVD process includes a chamber 11, in which a vacuum can be generated by means of a pump apparatus 12. The pressure in the chamber 12 for the HS-PVD is typically in the range of 0.1 mbar to 1 mbar.

A cathode arrangement 20 is provided in the chamber, which is designed as a hollow cathode arrangement, with cathode material being attached to the inside of the hollow cathode arrangement. In the illustrated embodiment the cathode arrangement 20 is designed to be linear, which means that the cathode material is designed in the form of plate-shaped elements 21. Two plate-shaped elements 21 are provided which are arranged in pairs parallel to one another. A rod-like anode 22 is provided which is connected to the cathode arrangement 20 via a DC voltage source 23. The DC voltage source 23 can for example deliver voltages of up to 1000 V, with which currents of up to 150 A can be generated. The working range varies, depending on the arrangement and the material, the apparatus can be operated with an output of a few kW up to approximately 150 kW. Further a cathode cooling system 25 is provided through which a coolant, for example water, can be conducted to the cathode arrangement 20 and away from this, as is indicated by the two arrows in FIG. 1.

A gas inlet 24 is provided at the underside of the cathode, which is connected via a gas supply line 14 to a not illustrated gas reservoir. An inert gas, preferably argon, flows through this gas inlet 24 in the operating state into the cathode arrangement 20. According to the design of the cathode arrangement 20, the gas inlet 24 can be designed as a distributor, which distributes the inert gas in the cathode arrangement 20 in a predetermined manner. The walls of the cathode arrangement 20 can also serve to feed the flow of inert gas. At the upper end of the cathode arrangement according to the drawing an outlet 26 is provided, which is preferably formed as a gap-shaped opening. The inert gas flows through the outlet 26 together with the sputtered cathode material out of the cathode arrangement 20.

In accordance with the drawing the base body 2 of a workpiece 1 is provided above the cathode arrangement 20, which is arranged in a holding device 15. The holding device 15 is rotatable by means of a motor, for example a servo-motor, as is indicated by the rotating arrow in FIG. 1, in order to guarantee as even a coating of the base body 2 as possible. The holding device 15 is further connected to a voltage source 17. The application of a bias voltage by means of the voltage source 17 can be used to accelerate the ionised part of the cathode material towards the base body 2 for layer compaction.

In the region of the workpiece 1 a heating apparatus 18 is further provided with which the base body 2 can be heated by means of thermal radiation or convection. Heating elements (not illustrated) of the heating apparatus are preferably provided on both sides of the base body 2 in order to heat this as evenly as possible to a homogenous temperature. Using the heating apparatus 18 the workpiece can be heated to 900° C. or more for example.

A pivotable screen 19 can also be provided between the outlet 26 of the cathode arrangement 20 and the workpiece 1, which screens the workpiece 2 against the outlet 26 in the pivoted state.

In accordance with the drawing, the outlet of a reactive gas feed 13 is provided beneath the pivotable screen 19, through which a reactive gas can be introduced into the chamber 11 and, in particular, into the flow of inert gas, which carries the sputtered cathode material with it. By this means it becomes possible to chemically modify sputtered cathode material, which is present in metallic form for example. Should, for example, a thermal barrier layer (TBC: thermal barrier coating) be deposited on the base body, then zirconium and yttrium can be sputtered in metallic form from the cathode material and oxygen can be introduced into the flow of material by the reactive gas supply, so that the zirconium and the yttrium are oxidised. A thermal barrier layer of yttrium-stabilised zirconium oxide is then deposited on the base body 2. Depending on the application, other reactive gases such as nitrogen, for example, can also be supplied.

It is self-evident that the arrangement of the individual components in the chamber 11 as described here are only to be understood as being an example. A horizontal arrangement can naturally also be provided in place of the vertical arrangement illustrated in FIG. 1.

To carry out the method in accordance with the invention a layer 3 of a platinum-modified nickel aluminide is deposited on the base body 2 by means of HS-PVD in this embodiment, wherein not only Pt, but also Al and Ni, are physically deposited out of the vapour phase. As an option it is also possible to additionally also integrate one or more active elements into the layer, in order to specifically modify their characteristics. The active elements are preferably selected from the following group: scandium (Sc), yttrium (Y), lanthanum (La), titanium (Ti), zirconium (Zr), hafnium (Hf), vanadium (V), niobium (Nb), tantalum (Ta), silicon (Si) and the lanthanides cerium (Ce) to lutetium (Lu), these are the elements of the atomic number 58 to 71. For practical reasons, three active elements at the most are preferably deposited, which amount to 0.2% to 10% by weight of the layer 3 in total.

The Pt and the Al content of the layer 3 preferably amounts to 10-35% by weight in each case and particularly preferably to 15-20% by weight in each case.

With a view to an improvement of the corrosion characteristics it can be advantageous to additionally also introduce chrome (Cr) with a concentration of 3% to 25% by weight into the layer 3.

The desired chemical composition of the layer 3 can be adjusted very precisely and in a manner, which can be reproduced by the design of the plate-shaped elements 21 with the cathode material. It is, moreover, possible, for example, to initially mix or alloy the elements, which the layer is intended to contain, in the pre-determinable stoichiometry or with the pre-determinable concentration proportions and subsequently to manufacture the plate-shaped elements 21 out of this mixture. It is further possible to manufacture the plate-shaped elements 21 in segments, so that the plate-shaped elements 21 have different zones, in which different materials are provided. The correct concentration ratios can be adjusted via the size and position of these zones. A combination of these two alternatives is naturally also possible. It is further possible to specifically modify components of the layer to be applied by feeding of a reactive gas through the reactive gas feed 13.

By means of this possibility of adjusting the chemical composition of the layer 3 reproducibly and exactly via the design of the cathode material, the PVD method is considerably more flexible than the CVD method with regard to the processable materials and the realisable concentration ranges of the individual components.

The plate-shaped elements 21 designed corresponding to the desired composition of the layer 3 with the cathode material are mounted in the cathode arrangement 20 for the application of the layer 3. In order to optimise the deposition process, the base body 2 is heated to a pre-determined temperature, for example 900° C., by means of the heating apparatus 18.

In the cathode arrangement 20 inert gas, preferably argon, is introduced through the gas inlet 24. The argon is ionised due to the voltage difference between the anode 22 and the cathode arrangement 20. The ionised argon particles are accelerated towards cathode material located on the plate-shaped elements 21 and on impingement there strike atoms, in other words for example, metallic Pt, Al and Ni, or atom clusters out of the surface 211 of the elements 21. The released or sputtered cathode material is then transported in the flow of inert gas through the outlet 26 in the direction of the base body 2, where it is deposited in the form of the layer 3. In this arrangement the base body 2 is rotated by means of the holding device 15 and of the motor 16, so that a layer 3 develops which is as even as possible.

The particular advantage of the HS-PVD method is to be seen in the fact that very high deposition rates of, for example, 100 μm/h can be achieved.

Since, in PVD methods, the platinum (and naturally also the other metallic elements) are deposited out of the gas phase directly in metallic form, contaminants such as those resulting for example in galvanic deposition due to the salts used, can be avoided. Disadvantageous incorporation of sulphur or phosphorous can be avoided in this way.

In relation to the way of carrying out the process, several alternatives are possible. Thus it is possible, for example, in a first method step to initially deposit a platinum layer and subsequently to deposit the other components of the layer 3 in one or more method steps. In this respect, the cathode material is changed, manually or automatically, between the individual method steps. In manual exchange the plate-shaped elements 21 or parts thereof are exchanged, for example. Naturally, several cathode arrangements can also be provided, which, for example, can be selectively activated. A further alternative is to displace the gas inlet 24 or rather the gas distributor, so that it is immersed more or less deeply into the cathode arrangement. This measure is advantageous, particularly for partial alloying.

Using this way of carrying out the process, the two-stage process can be imitated, which is carried out in the CVD method known per se with prior galvanic deposition of the Pt layer.

On the other hand, it is also possible to deposit all components of the layer 3 in one method step, essentially simultaneously. In addition several cathode arrangements 20 arranged one after the other, for example, can also be provided.

In particular in those cases in which the layer 3 is deposited in more as one method step, it can be advantageous to subject the coated base body 3 subsequently to a heat treatment known per se, in order to make the layer 3 as homogenous as possible by means of diffusion processes.

It is naturally also possible to consciously design the layer 3 with more than one phase.

The PVD process is carried out at a process pressure in the chamber of at least 0.1 mbar. For this purpose, the chamber 11 is first pumped down to a starting vacuum of at least 5×10⁻³ mbar and the PVD process is subsequently carried out at least 0.1 mbar. The process pressure preferably amounts to at least 4×10⁻¹ mbar and especially to between 4×10⁻¹ mbar and 6×10⁻¹ mbar. For this process pressure, the chamber is first evacuated to a starting vacuum of 10⁻³ mbar. At such process pressures, one lies considerably above those which are for example used for a typical EB-PVD process. For EB-PVD the process pressure normally amounts to 10⁻³ mbar to 2×10⁻² mbar, with the evacuation being carried out to a starting pressure of 10⁻⁵ mbar to 10⁻⁶ mbar.

A further alternative of the method in accordance with the invention is, after the production of the layer 3, to apply a thermal barrier layer (TBC) to it. The TBC layer can be applied by means of all methods known per se, in other words for example by means of a PVD method or by means of a thermal spraying process. The TBC layer 4 can consist of all materials known for this purpose, in other words for example of completely or partially yttrium stabilised zirconium oxide (YSZ), of a combination of YSZ with a third oxide or with the new TBC materials such as spinels, perovscites and pyrochlors.

The method in accordance with the invention is in particular suitable for the production of hot corrosion resistant and hot oxidation resistant protective layers on turbine blades or other gas turbine components, which are heavily exposed to heat.

1. A method for the coating of a base body, in which a layer of a platinum modified aluminide of the kind PtMAI is produced on the base body, wherein M designates the metals iron (Fe) or nickel (Ni) or cobalt (Co) or combinations of these metals, characterised in that the layer is produced by means of a physical deposition out of the gas phase (PVD), wherein at least the two components aluminium (Al) and metal M are physically deposited out of the vapour phase, with the deposition being carried out at a process pressure of at least 0.1 mbar, preferably of at least 0.4 mbar and especially between 0.4 and 0.6 mbar.

2. A method in accordance with claim 1, in which all the components aluminium (Al), platinum (Pt) and the metal M are physically deposited out of the vapour phase.

3. A method in accordance with claim 1 in which the platinum is applied galvanically and the components aluminium and metal M are physically deposited out of the vapour phase.

4. A method in accordance with claim 1, in which the layer additionally contains at least one active element, wherein each active element is selected from the group which includes scandium (Sc), yttrium (Y), lanthanum (La), titanium (Ti), zirconium (Zr), hafnium (Hf), vanadium (V), niobium (Nb), tantalum (Ta), silicon (Si) and the lanthanides cerium (Ce) to lutetium (Lu).

5. A method in accordance with claim 4 in which at least one active element is deposited physically out of the gas phase.

6. A method in accordance with claim 4, wherein one to three active elements are deposited which in total make 0.2 to 10% by weight of the layer.

7. A method in accordance with claim 1 in which chrome is additionally deposited physically out of the vapour phase and in total amounts to 3% to 25% by weight of the layer.

8. A method in accordance with claim 1 in which in a first method step a platinum layer is initially deposited and subsequently the other components of the layer are deposited in at least one further method step.

9. A method in accordance with claim 1 in which all components of the layer are deposited in one method step essentially simultaneously.

10. A method in accordance with claim 1 in which the physical deposition is carried out by means of high speed PVD (HS-PVD).

11. A method in accordance with claim 1 in which a thermal barrier layer (TBC) is subsequently applied to the layer.

12. A workpiece with a base body on which a layer is applied which is produced using a method in accordance with claim 1.

13. A workpiece in accordance with claim 12, formed as a turbine blade.
